(19) United States
(12) Patent Application Publication
(10) Pub. No.: US 2014/0306746 A1
(43) Pub. Date: Oct. 16, 2014

(54) DYNAMIC CLOCK SKEW CONTROL

(71) Applicant: ADVANCED MICRO DEVICES, INC., Sunnyvale, CA (US)

(72) Inventor: Thomas L. Meneghini, Groton, MA (US)

(73) Assignee: Advanced Micro Devices, Inc., Sunnyvale, CA (US)

(21) Appl. No.: 13/862,961

(22) Filed: Apr. 15, 2013

(51) Int. Cl. H03K 3/01

(52) U.S. Cl. CPC H03K 3/01
USPC 327/291

(57) ABSTRACT

A device includes a dock generator operable to generate a clock signal. A first module includes a first clock network coupled to the clock generator for distributing the clock signal. A second module includes a second clock network coupled to the clock generator for distributing the clock signal. A clock skew control circuit is operable to receive a first instance of the clock signal from the first clock network and a second instance of the clock signal from the second clock network and to control skew between the first and second instances of the clock signal.

### FIELD OF THE DISCLOSURE

The present disclosure relates generally to computing systems and more particularly to clock matching.

### BACKGROUND

In computing devices a common clock signal is distributed to multiple functional units. For example, a processor core and a cache on the same die may employ clocks having the same frequency that are each based on a common clock signal. A clock distribution tree provides the common clock signal to the processor core and the cache. However, process variations and variations in operating conditions can result in the clock signal that reaches the processor core (the core clock) having a phase mismatch, or skew, relative to the clock signal that reaches the cache (the cache clock). For the processor core to communicate with the cache the skew between the core clock and the cache clock should be limited, or timing errors may arise.

One technique for reducing clock skew between functional units is to introduce a fixed delay into one of the clock paths, thereby phase aligning the clocks at the different functional units. During the testing phase of an integrated circuit device, the clock skew may be measured and fusible links may be programmed to configure a programmable delay path to mitigate the skew.

### BRIEF DESCRIPTION OF THE DRAWINGS

The present disclosure may be better understood, and its numerous features and advantages made apparent to those skilled in the art by referencing the accompanying drawings.

FIG. 1 is a block diagram of a processing system including a processor, a memory, and a clock distribution circuit in accordance with some embodiments.

FIG. 2 is a block diagram of the skew controller in the clock distribution circuit of FIG. 1 in accordance with some embodiments.

FIG. 3 is a flow diagram of a method for controlling clock skew between modules of an integrated circuit device in accordance with some embodiments.

FIG. 4 is a flow diagram illustrating an example method for the design and fabrication of an integrated circuit device implementing one or more aspects in accordance with some embodiments.

The use of the same reference symbols in different drawings indicates similar or identical items.

### DETAILED DESCRIPTION

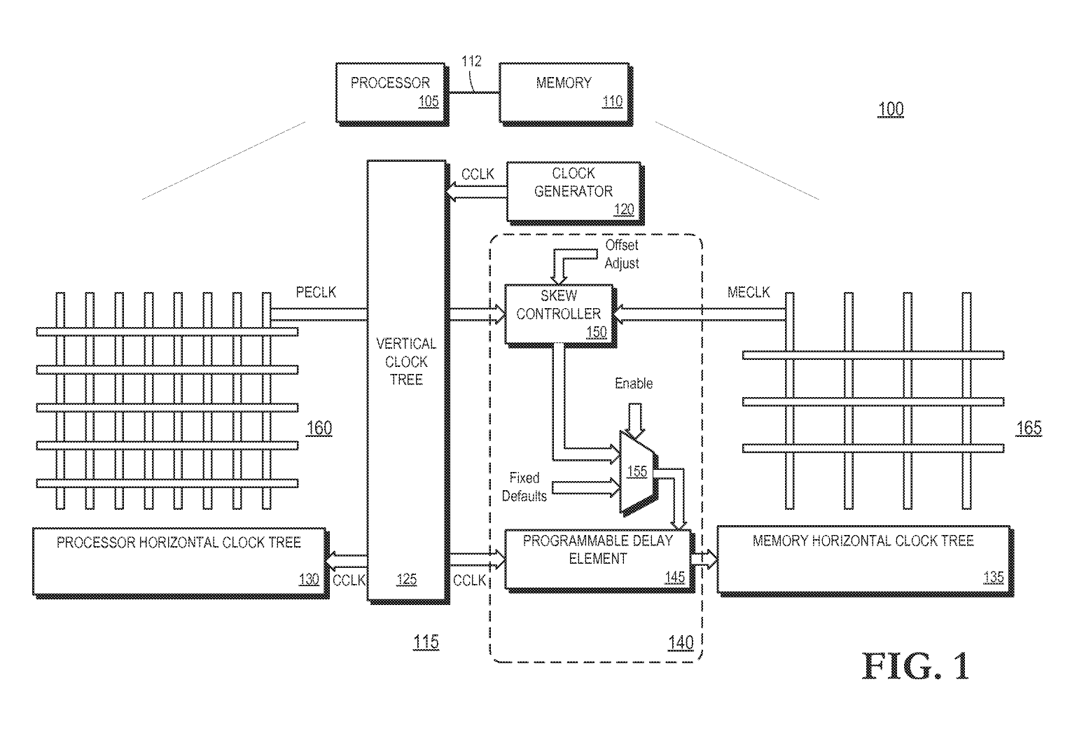

FIGS. 1-3 illustrate example techniques for controlling clock skew between modules in an integrated circuit device. A common clock signal is distributed to different modules of the integrated circuit device, such as a processor and a memory. Instances of the clock signal from the modules are compared to dynamically control skew therebetween so that communication may occur over an interface between the modules. Dynamic skew control addresses various causes for skew, such as process variation, temperature variation, noise, voltage variation, age-based degradation, and the like, thereby reducing potential errors in communication between the modules.

FIG. 1 illustrates a processing system 100 in accordance with some embodiments. The processing system 100 can be used in any of a variety of electronic devices, such as a personal computer, server, portable electronic device such as a cellular phone or smartphone, a game system, set-top box, and the like. The processing system 100 generally stores and executes instructions organized as computer programs in order to carry out tasks defined by the computer programs, such as data processing, communication with other electronic devices via a network, multimedia playback and recording, execution of computer applications, and the like.

The processing system 100 includes a processor 105 and a memory 110 communicating over an interface 112. The memory 110 may represent one or more levels in a memory hierarchy of the processing system 100. The memory 110 is generally configured both to store the instructions to be executed by the processor 105 in the form of computer programs and to store the data that is manipulated by the executing instructions. The processing system 100 implements one or more memories 110. For example, the memory 110 may represent a cache memory. In some embodiments, the cache memory may be on the same die as the processor 105 and may operate using a common clock signal. For example, the processor 105 may have an internal L1 cache (not shown), and the memory 110 may be an L2 cache.

The processor 105 and the memory 110 operate using instances of a common clock signal, denoted as “CCLK”. The CCLK signal is generated and distributed by a clock distribution circuit 115 including a clock generator 120 (e.g., a phase locked loop (PLL)) for generating the CCLK signal, a vertical clock tree 125 coupled to the clock generator 120, a processor horizontal clock tree 130 coupled to the vertical clock tree 125, a memory horizontal clock tree 135 coupled to the vertical clock tree 125, and a clock skew control circuit 140. The clock skew control circuit 140 includes a programmable delay element 145 coupled between the vertical clock tree 125 and the memory horizontal clock tree 135, a skew controller 150, and a multiplexer 155. To facilitate communication over the interface 112 between the processor 105 and the memory 110, the clock signals are synchronized by the clock skew control circuit 140.

The clock generator 120 generates the CCLK signal and provides it to the vertical clock tree 125. The vertical clock tree 125 sends the CCLK signal to the processor horizontal clock tree 130, where it is distributed to a processor clock grid 160. The processor horizontal clock tree 130 and the processor clock grid 160 distribute the CCLK signal throughout the processor 105, defining a processor clock network. The vertical clock tree 125 also sends the CCLK signal to the memory horizontal clock tree 135 through the programmable delay element 145, where it is distributed to a memory clock grid 165. The memory horizontal clock tree 135 and the memory clock grid 165 distribute the CCLK signal throughout the memory 110, defining a memory clock network.

The processor clock grid 160 and the memory clock grid 165 exhibit different characteristics that affect the degree to which the CCLK signal is delayed as it is distributed. These characteristics include process variation characteristics, thermal characteristics, noise characteristics voltage characteristics, degradation characteristics, etc. The delay in a clock signal resulting from these and other characteristics of a clock network is referred to as the “insertion delay” of the clock network.

The instance of the clock signal from the processor clock grid 160, denoted as “PECLK” for processor exit clock, and the instance of the clock signal from the memo clock grid 165, denoted as “MECLK” for memory exit clock, are provided to the skew controller 150 for comparison.

Although the present subject matter is described as it applies to a processor clock network and a memory clock network, it may be applied to any modules in an integrated circuit device that receive a common clock signal to distribute to their respective clock networks (e.g., defined by the trees 130, 135 and the grids 160, 165), which have the potential to exhibit different insertion delays. The exit clocks from the clock networks may be compared as described herein to control the skew between the clock signals.

The programmable delay element 145 receives a multi-bit control input from the multiplexer 155 and configures its delay based on the value of the control input. The multiplexer 155 selects between a variable control input provided by the skew controller 150 and a fixed control input (e.g., “Fixed Defaults” in FIG. 1). For example, a static value for the programmable delay element 145 may be set using fusible elements, and the value for the delay may be characterized during qualification testing of the die within the production cycle.

Using a fixed skew correction approach fails to address other dynamic sources of clock skew, such as thermal effects, noise, voltage, and degradation due to aging. The thermal characteristics of the processor 105 vary significantly from those of the memory 110. The memory 110 consumes a relatively large die area, yet it consumes very little dynamic power due to its low activity factor. In contrast, the dynamic power consumed by the processor 105 varies significantly due to program activity factors, which results in significant temperature swings. The clock skew between the processor 105 and the memory 110 increases in times of heavy processing load. In addition, components in the processor 105 and the memory 110 degrade over time due to factors such as positive and negative bias temperature instability (BTI). This degradation introduces additional timing variation that can affect clock skew. Noise and voltage variation are dynamic factors that introduce skew variability depending on the particular operating environment.

To address the dynamic skew components, margin is added to the timing paths between the processor and the cache. Providing this additional margin results in a decrease in performance of the processing system 100.

An enable input to the multiplexer 155 selects the skew controller 150 as the source for the control input to the programmable delay element 145 to enable dynamic skew control. In some embodiments, the multiplexer 1155 may be omitted and the static control input option may not be implemented. In such embodiments, the skew controller 150 would be connected directly to the programmable delay element 145. The enable input may be generated based on the value of a bit in a configuration register or by a fused input. In embodiments with a configuration register, the value that determines the state of the enable signal may be set during a boot routine of the processing system 100.

The skew controller 150 compares the PECLK and MECLK signals to determine the presence of any skew by comparing the phases of the signals. The phase difference may be quantified by comparing arrival times for rising edges of the signals. The skew controller 150 provides a control input to the programmable delay element 145 to set its delay value, thereby adjusting the phase of the MECLK signal. The skew controller 150 employs a control loop using feedback values provided by the PECLK and MECLK signals to generate an error signal. The skew controller 150 changes the control input to the programmable delay element 145 based on the error signal to reduce the skew.

In some embodiments, the skew controller 150 may control the skew between the PECLK and MECLK signals to generate a predetermined amount of offset (i.e., an intentional amount of skew). The skew offset may be determined based on the timing paths during testing, and may be varied to optimize the performance of the processing system 100. The skew controller 150 receives an offset input that determines the desired predetermined skew amount. The value for the skew offset may be determined during device qualification testing, and fusible elements may be configured to define the offset. Alternatively, in some embodiments, a register may be used to store the value of the skew offset.

The skew controller 150 dynamically adjusts the programmable delay element 145 to control skew between the PECLK and MECLK signals, thereby accounting for both dynamic and fixed sources of skew. For example, dynamic temperature changes in the processor 105 relative to the memory 110 resulting from periods of high processor activity can be dynamically addressed and the temperature induced skew can be mitigated. Intermittent skew factors, such as voltage variation or noise, as well as slow acting skew-inducing factors, such as age degradation can also be mitigated by the clock skew control circuit 140.

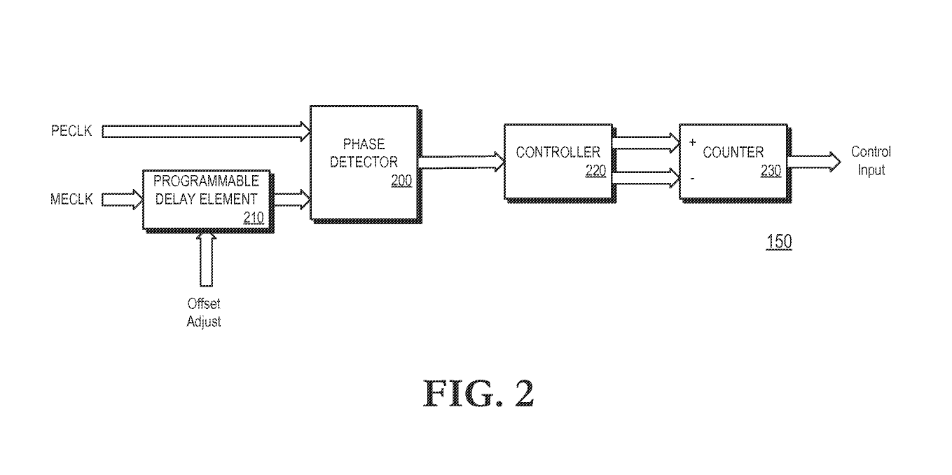

FIG. 2 is a block diagram of the skew controller 150 in accordance with some embodiments. The skew controller 150 includes a phase detector 200, a programmable delay element 210, a controller 220, and a counter 230. The phase detector 200 measures arrival times of the PECLK and MECLK signals to determine the presence of any skew. The phase detector 200 provides a 1-bit output indicating which input signal arrived first. The controller 220 receives the output of the phase detector 200 and adjusts a value of the counter 230 to increase or decrease the amount of delay provided by the programmable delay element 145 (see FIG. 1). If the error signal indicates that the PECLK lags the MECLK, the controller 220 increments the counter 230, and if the error signal indicates that the PECLK leads the MECLK, the controller decrements the counter 230.

In some embodiments, the performance of the processing system 100 may be optimized when the skew between the processor 105 and the memory 110 is not zero, but rather, some finite amount. In such cases, the skew controller 150 may control the clock signals to generate a predetermined amount of skew at steady state. The skew controller 150 adjusts the programmable delay element 145 of FIG. 1 under dynamic conditions to maintain that predetermine amount of skew. The programmable delay element 210 is configured using the offset adjust parameter to inject a fixed delay in the MECLK signal used for measuring the skew. This fixed delay adjusts the measured phase error between the actual PECLK and MECLK signals such that when the phase error seen by the phase detector 200 goes to zero, there will be a non-zero skew between the actual PECLK and MECLK signals. In some embodiments, the controller 220 may receive the offset adjust parameter and control the counter 230 directly to provide the fixed skew, obviating the need for the programmable delay element 210.

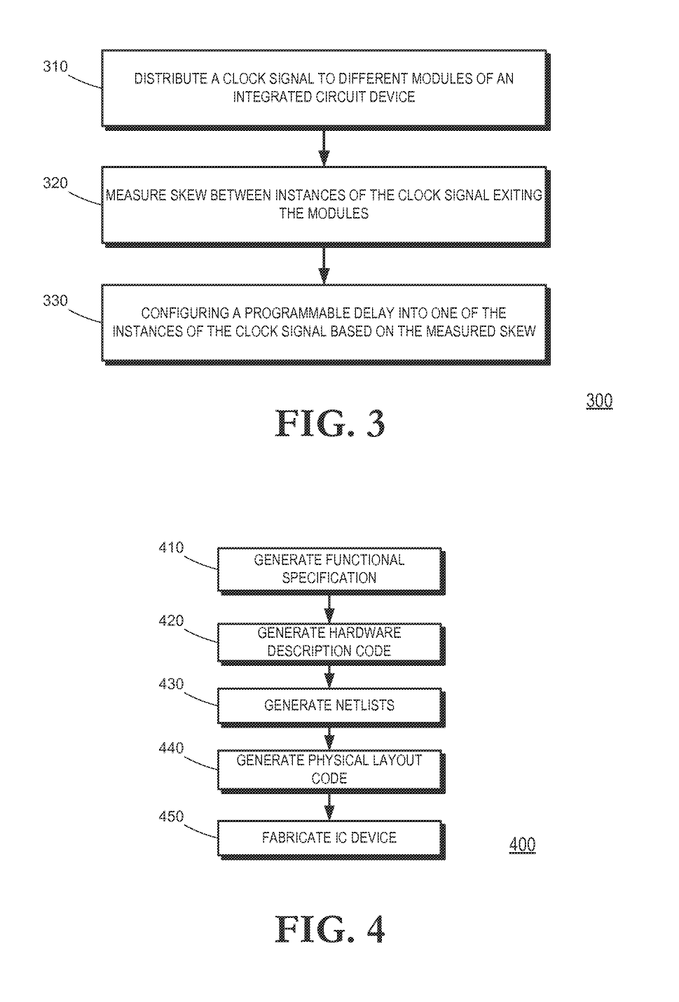

The general operation of the clock skew control circuit of FIG. 1 is illustrated further in FIG. 3, which is a flow diagram of a method fir controlling clock skew between modules of an integrated circuit device in accordance with some embodiments. In method block 310, a clock signal, CCLK, is distributed to different modules of an integrated circuit device 100, such as the processor 105 and the memory 110. In method block 320, the skew between instances of the clock signal, PECLK and MECLK, from the modules (e.g., processor 105 and memory 110) is measured. In method block 330, a programmable delay is introduced into one of the instances of the clock signal based on the measured skew.

In some embodiments, the devices and techniques described above are implemented in a system comprising one or more integrated circuit (IC) devices (also referred to as integrated circuit packages or microchips), such as the processor described above with reference to FIGS. 1-3. Electronic design automation (EDA) and computer aided design (CAD) software tools may be used in the design and fabrication of these IC devices. These design tools typically are represented as one or more software programs. The one or more software programs comprise code executable by a computer system to manipulate the computer system to operate on code representative of circuitry of one or more IC devices so as to perform at least a portion of a process to design or adapt a manufacturing system to fabricate the circuitry. This code can include instructions, data, or a combination of instructions and data. The software instructions representing a design tool or fabrication tool typically are stored in a computer readable storage medium accessible to the computing system. Likewise, the code representative of one or more phases of the design or fabrication of an IC device may be stored in and accessed from the same computer readable storage medium or a different computer readable storage medium.

A computer readable storage medium may include any storage medium, or combination of storage media, accessible by a computer system during use to provide instructions and/or data to the computer system. Such storage media can include, but is not limited to, optical media (e.g., compact disc (CD), digital versatile disc (DVD), Blu-Ray disc), magnetic media (e.g., floppy disc, magnetic tape, or magnetic hard drive), volatile memory (e.g., random access memory (RAM) or cache), non-volatile memory (e.g., read-only memory (ROM) or Flash memory), or microelectromechanical systems (MEMS)-based storage media. The computer readable storage medium may be embedded in the computing system (e.g., system RAM or ROM), fixedly attached to the computing system (e.g., a magnetic hard drive), removably attached to the computing system (e.g., an optical disc or Universal Serial Bus (USB)-based Flash memory), or coupled to the computer system via a wired or wireless network (e.g., network accessible storage (NAS)).

FIG. 4 is a flow diagram illustrating an example method 400 for the design and fabrication of an IC device implementing one or more aspects in accordance with some embodiments. As noted above, the code generated for each of the following processes is stored or otherwise embodied in computer readable storage media for access and use by the corresponding design tool or fabrication tool.

At block 410 a functional specification for the IC device is generated. The functional specification (often referred to as a micro architecture specification (MAS)) may be represented by any of a variety of programming languages or modeling languages, including C, C++, SystemC, Simulink, or MATLAB.

At block 420, the functional specification is used to generate hardware description code representative of the hardware of the IC device. In some embodiments, the hardware description code is represented using at least one Hardware Description Language (HDL), which comprises any of a variety of computer languages, specification languages, or modeling languages for the formal description and design of the circuits of the IC device. The generated HDL code typically represents the operation of the circuits of the IC device, the design and organization of the circuits, and tests to verify correct operation of the IC device through simulation. Examples of HDL include Analog HDL (AHDL), Verilog HDL, SystemVerilog HDL, and VHDL. For IC devices implementing synchronized digital circuits, the hardware descriptor code may include register transfer level (RTL) code to provide an abstract representation of the operations of the synchronous digital circuits. For other types of circuitry, the hardware descriptor code may include behavior-level code to provide an abstract representation of the circuitry's operation. The model represented by the hardware description code typically is subjected to one or more rounds of simulation and debugging to pass design verification.

After verifying the design represented by the hardware description code, a synthesis tool is used to synthesize the hardware description code to generate code representing or defining an initial physical implementation of the circuitry of the IC device at block 430. In some embodiments, the synthesis tool generates one or more netlists comprising circuit device instances (e.g., gates, transistors, resistors, capacitors, inductors, diodes, etc.) and the nets, or connections, between the circuit device instances. Alternatively, all or a portion of a netlist can be generated manually without the use of a synthesis tool. As with the hardware description code, the netlists may be subjected to one or more test and verification processes before a final set of one or more netlists is generated.

Alternatively, a schematic editor tool can be used to draft a schematic of circuitry of the IC device and a schematic capture tool then may be used to capture the resulting circuit diagram and to generate one or more netlists (stored on a computer readable media) representing the components and connectivity of the circuit diagram. The captured circuit diagram may then be subjected to one or more rounds of simulation for testing and verification.

At block 440, one or more EDA tools use the netlists produced at block 430 to generate code representing the physical layout of the circuitry of the IC device. This process can include, for example, a placement tool using the netlists to determine or fix the location of each element of the circuitry of the IC device. Further, a routing tool builds on the placement process to add and route the wires needed to connect the circuit elements in accordance with the netlist(s). The resulting code represents a three-dimensional model of the IC device. The code may be represented in a database file format, such as, for example, the Graphic Database System II (GDSII) format. Data in this format typically represents geometric shapes, text labels, and other information about the circuit layout in hierarchical form.

At block 450, the physical layout code (e.g., GDSII code) is provided to a manufacturing facility, which uses the physical layout code to configure or otherwise adapt fabrication tools of the manufacturing facility (e.g., through mask works) to fabricate the IC device. That is, the physical layout code may be programmed into one or more computer systems, which may then control, in whole or part, the operation of the tools of the manufacturing facility or the manufacturing operations performed therein.

Dynamic skew control, as described herein has numerous advantages. Reducing the amount of skew that exists between clock networks allows timing margins to be reduced and, as a result, clock frequency can be increased. The dynamic skew control provided by the clock skew control circuit 140 eliminates or reduces (i.e., the sampling rate for skew characterization may be reduced) the need to characterize the skew during testing to develop a fuse recipe for the static control input. This reduction in characterization reduces the production cycle and requires less tester time, thereby increasing throughput. Because, the timing margins can be more aggressive due to the dynamic skew control, smaller and lower power gates may be employed for a given design, resulting in lower overall power consumption. Because the clock skew control circuit 140 mitigates skew regardless of source, aging effects can be addressed, resulting in increased longevity for the processing system 100.

According to some embodiments, a device includes a clock generator operable to generate a clock signal. A first module includes a first clock network coupled to the clock generator for distributing the clock signal. A second module includes a second clock network coupled to the clock generator for distributing the clock signal. A clock skew control circuit is operable to receive a first instance of the clock signal from the first clock network and a second instance of the clock signal from the second clock network and to control skew between the first and second instances of the clock signal.

According to some embodiments, a processing system includes a clock generator operable to generate a clock signal, a processor, a memory, and a clock skew control circuit. The processor includes a first clock network coupled to the clock generator for distributing the clock signal. The memory includes a second clock network coupled to the clock generator for distributing the clock signal. The clock skew control circuit is operable to receive a first instance of the clock signal from the first clock network and a second instance of the clock signal from the second clock network and to control skew between the first and second instances of the clock signal.

According to some embodiments, a method includes distributing a clock signal to a first module of an integrated circuit device. The clock signal is distributed to a second module of the integrated circuit device. Skew between a first instance of the clock signal from the first module and a second instance of the clock signal from the second module is controlled.

According to some embodiments, a non-transitory computer readable medium stores code to adapt at least one computer system to perform a portion of a process to fabricate at least part of an integrated circuit device. The device includes a clock generator operable to generate a clock signal. A first module includes a first clock network coupled to the clock generator for distributing the clock signal. A second module includes a second clock network coupled to the clock generator for distributing the clock signal. A clock skew control circuit is operable to receive a first instance of the clock signal from the first clock network and a second instance of the clock signal from the second clock network and to control skew between the first and second instances of the clock signal.

In some embodiments, certain aspects of the techniques described above may implemented by one or more processors of a processing system executing software. The software comprises one or more sets of executable instructions stored on a computer readable medium that, when executed by the one or more processors, manipulate the one or more processors to perform one or more aspects of the techniques described above. The software is stored or otherwise tangibly embodied on a computer readable storage medium accessible to the processing system, and can include the instructions and certain data utilized during the execution of the instructions to perform the corresponding aspects.

Note that not all of the activities or elements described above in the general description are required, that a portion of a specific activity or device may not be required, and that one or more further activities may be performed, or elements included, in addition to those described. Still further, the order in which activities are listed are not necessarily the order in which they are performed.

Also, the concepts have been described with reference to specific embodiments. However, one of ordinary skill in the art appreciates that various modifications and changes can be made without departing from the scope of the present disclosure as set forth in the claims below. Accordingly, the specification and figures are to be regarded in an illustrative rather than a restrictive sense, and all such modifications are intended to be included within the scope of the present disclosure.

Benefits, other advantages, and solutions to problems have been described above with regard to specific embodiments. However, the benefits, advantages, solutions to problems, and any feature(s) that may cause any benefit, advantage, or solution to occur or become more pronounced are not to be construed as a critical, required, or essential feature of any or all the claims.

What is claimed is:

1. An integrated circuit device, comprising:
a clock generator operable to generate a clock signal;
a first module including a first clock network coupled to the clock generator for distributing the clock signal;
a second module including a second clock network coupled to the clock generator for distributing the clock signal; and
a clock skew control circuit operable to receive a first instance of the clock signal from the first clock network and a second instance of the clock signal from the second clock network and to control skew between the first and second instances of the clock signal.

2. The device of claim 1, wherein the clock skew control circuit comprises:
a programmable delay element coupled between the clock generator and the second clock network; and
a skew controller operable to compare the first and second instances of the clock signal and control a delay imposed by the programmable delay element based on the comparison.

3. The device of claim 2, wherein the skew controller is operable to compare the first and second instances of the clock signal by comparing a first arrival time of an edge of the first instance of the clock signal to a second arrival time of an edge of the second instance of the clock signal.

4. The device of claim 2, wherein the first clock network includes a first horizontal clock tree, the second clock network includes a second horizontal clock tree, and the device further comprises a vertical clock tree coupled to the clock generator and operable to distribute the clock signal to the first and second horizontal clock trees.

5. The device of claim 4, wherein the programmable delay element coupled between the vertical clock tree and the second horizontal clock tree.

6. The device of claim 2, wherein the skew controller is operable to control the delay to generate a predetermined amount of skew between the first and second instances of the clock signal.

7. The device of claim 2, wherein the clock skew control circuit comprises a multiplexer having an output terminal coupled to the programmable delay element, a first input terminal coupled to the skew controller, and a second input terminal coupled to a fixed control input representing a fixed delay for the programmable delay element.

8. A processing system, comprising:
a clock generator operable to generate a clock signal;
a processor including a first clock network coupled to the clock generator for distributing the clock signal;
a memory including a second clock network coupled to the clock generator for distributing the clock signal; and
a clock skew control circuit operable to receive a first instance of the clock signal from the first clock network and a second instance of the clock signal from the second clock network and to control skew between the first and second instances of the clock signal.

9. The processing system of claim 8, wherein the clock skew control circuit comprises:
a programmable delay element coupled between the clock generator and the second clock network; and
a skew controller operable to compare the first and second instances of the clock signal and control a delay imposed by the programmable delay element based on the comparison.

10. The processing system of claim 9, wherein the skew controller is operable to compare the first and second instances of the clock signal by comparing a first arrival time of an edge of the first instance of the dock signal to a second arrival time of an edge of the second instance of the clock signal.

11. The processing system of claim 9, wherein he first clock network includes a first horizontal dock tree, the second clock network includes a second horizontal clock tree, and the device further comprises a vertical clock tree coupled to the clock generator and operable to distribute the clock signal to the first and second horizontal clock trees.

12. The processing system of claim 11, wherein the programmable delay element is coupled between the vertical clock tree and the second horizontal clock tree.

13. The processing system of claim 9, wherein the skew controller is operable to control the delay to generate a predetermined amount of skew between the first and second instances of the clock signal.

14. The processing system of claim 9, wherein the dock skew control circuit comprises a multiplexer having an output terminal coupled to the programmable delay element, a first input terminal coupled to the skew controller, and a second input terminal coupled to a fixed control input.

15. A method, comprising:
distributing a clock signal to a first module of an integrated circuit device;
distributing the clock signal to a second module of the integrated circuit device; and
controlling skew between a first instance of the clock signal from the first module and a second instance of the clock signal from the second module.

16. The method of claim 15, wherein controlling the skew further comprises comparing arrival times of edges of the first and second instances of the clock signal.

17. The method of claim 15, wherein controlling the skew further comprises controlling the skew to include a predetermined amount of skew between the first and second instances of the clock signal.

18. The method of claim 15, wherein controlling the skew further comprises introducing a delay in the second instance in the clock signal based on the comparison.

19. The method of claim 15, wherein controlling the skew further comprises configuring a programmable delay element to introduce a delay in the second instance in the clock signal based on the comparison.

20. The method of claim 19, further comprising configuring the programmable delay element with one of a first control input determined based on the comparison or a second control input representing a fixed control input.
